(19) United States
(12) Patent Application Publication
(10) Pub. No.: US 2010/0321544 A1
(43) Pub. Date: Dec. 23, 2010

(54) SEMICONDUCTOR DEVICE, CAMERA MODULE AND METHOD OF MANUFACTURING SEMICONDUCTOR DEVICE

(75) Inventors: Mie MATSUO, Kanagawa (JP); Kenichiro HAGIWARA, Kanagawa (JP); Akira KOMATSU, Ishikawa (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/797,761

(22) Filed: Jun. 10, 2010

(30) Foreign Application Priority Data
Jun. 22, 2009 (JP) 2009-148098

(51) Int. Cl. H04N 5/335; H01L 23/48; H01L 21/768

(52) U.S. Cl. 348/294; 257/774; 438/667; 257/773; 257/E21.597; 257/E23.011; 348/E05.091

(57) ABSTRACT

A semiconductor device comprises a semiconductor substrate, a through contact and a metal film. The semiconductor substrate has a semiconductor element at a first face. The wiring pattern includes a grounding line and is located at a side of a second face opposite to the first face of the semiconductor substrate. The through contact penetrates the semiconductor substrate from the first face to the second face and electrically connects between the semiconductor element and the wiring pattern. The metal film is located between the second face of the semiconductor substrate and a face where the wiring pattern exists and electrically connected with the grounding line.

### CROSS-REFERENCE TO RELATED APPLICATIONS

This application is based upon and claims the benefit of priority from the prior Japanese Patent Application No. 2009-148098, filed on Jun. 22, 2009; the entire contents of which are incorporated herein by reference.

### BACKGROUND

1. Field

Embodiments relate to a semiconductor device, a camera module and a method of manufacturing a semiconductor device.

2. Description of the Related Art

Recently, along with a progress in downsizing and trim-weighting of electrical devices, demand for downsizing of a camera module especially used for a cell phone, or the like, has been arose. Accordingly, a package with a CSP (chip scale package) structure having BGA (ball grid array) type terminals has become to be adopted more as a package for a camera module. In the camera module with the BGA type terminals, for instance, a wiring pattern is formed on a surface (hereinafter to be referred to as back face) opposite to a surface (hereinafter to be referred to as upper surface) on which an image sensor is formed in a semiconductor substrate, and the wiring pattern on the back face of the substrate and the image sensor on the upper face of the substrate are connected via electrodes which are formed inside the substrate or on a side face of the substrate. By this arrangement, it may be possible to make the semiconductor substrate with the image sensor thin, as a result of which the camera module can be made further downsized and thin.

However, in the camera module according to the prior art, due to light from the back face of the substrate entering the image sensor formed on the upper face via the substrate, appearance of ghosts, capture of the wiring pattern on the back face of the substrate, etc. may occur. As technique for solving such phenomena, for instance, a technique of forming a light reflection layer or a light absorbing layer each of which shields light entering the back face of the substrate from something other than a subject.

However, in such structure as in the prior art described above where electrical connections with the image sensor formed on the upper face of the substrate are drawn to the back face of the substrate using through contacts that penetrate the substrate, parasitic capacitance and parasitic resistance occur between the substrate and the wiring pattern on the back face of the substrate, whereby a waveform of the high-frequency signal may become dull. Therefore, a high-speed operation of the solid-state image sensor may become difficult. Such difficulties may not be resolved even if the blackout layer to be formed on the back face of the substrate is formed as a metal layer, for instance. That is, even if a metal layer is formed on the back face of the substrate, due to the metal layer floating electrically, the above-described phenomena that can be caused by the parasitic capacitance and the parasitic resistance may not be resolved.

### BRIEF DESCRIPTION OF THE DRAWINGS

FIG. 1 is a cross-sectional schematic diagram showing an outline structure of a camera module according to a first embodiment of the present invention;

FIG. 2 is a cross-sectional schematic diagram showing an outline structure of a semiconductor device according to the first embodiment of the present invention;

FIG. 3 is an overhead view showing an outline structure of the semiconductor device according to the first embodiment of the present invention;

FIG. 4A is a process illustration showing a manufacturing method of the camera module according to the first embodiment of the present invention (phase 1);

FIG. 4B is a process illustration showing the manufacturing method of the camera module according to the first embodiment of the present invention (phase 2);

FIG. 4C is a process illustration showing the manufacturing method of the camera module according to the first embodiment of the present invention (phase 3);

FIG. 4D is a process illustration showing the manufacturing method of the camera module according to the first embodiment of the present invention (phase 4);

FIG. 4E is a process illustration showing the manufacturing method of the camera module according to the first embodiment of the present invention (phase 5);

FIG. 4F is a process illustration showing the manufacturing method of the camera module according to the first embodiment of the present invention (phase 6);

FIG. 4G is a process illustration showing the manufacturing method of the camera module according to the first embodiment of the present invention (phase 7);

FIG. 4H is a process illustration showing the manufacturing method of the camera module according to the first embodiment of the present invention (phase 8);

FIG. 4I is a process illustration showing the manufacturing method of the camera module according to the first embodiment of the present invention (phase 9);

FIG. 4J is a process illustration showing the manufacturing method of the camera module according to the first embodiment of the present invention (phase 10);

FIG. 4K is a process illustration showing the manufacturing method of the camera module according to the first embodiment of the present invention (phase 11);

FIG. 4L is a process illustration showing the manufacturing method of the camera module according to the first embodiment of the present invention (phase 12);

FIG. 5 is an overhead view showing an outline structure of a semiconductor device according to an alternate example 1-1 of the first embodiment of the present invention;

FIG. 6 is a cross-sectional view showing an outline structure of a semiconductor device according to an alternate example 1-2 of the first embodiment of the present invention;

FIG. 7A is a process illustration showing a manufacturing method of the camera module according to an alternate example 1-3 of the first embodiment of the present invention (phase 1);

FIG. 7B is a process illustration showing the manufacturing method of the camera module according to the alternate example 1-3 of the first embodiment of the present invention (phase 2);

FIG. 7C is a process illustration showing the manufacturing method of the camera module according to the alternate example 1-3 of the first embodiment of the present invention (phase 3);

FIG. 7D is a process illustration showing the manufacturing method of the camera module according to the alternate example 1-3 of the first embodiment of the present invention (phase 4);

FIG. 8 is an overhead view showing an outline structure of a semiconductor device according to a second embodiment of the present invention;

FIG. 9 is a B-B cross-sectional view showing an outline structure of the semiconductor device shown in FIG. 8;

FIG. 10 is an overhead view showing an outline structure of a semiconductor device according to a third embodiment; and

FIG. 11 is a C-C cross-sectional view showing an outline structure of the semiconductor device shown in FIG. 10.

### DETAILED DESCRIPTION OF THE INVENTION

In the following, a semiconductor device, a camera module and a method of manufacturing a semiconductor device according to embodiments of the present invention will be described in detail with reference to the accompanying drawings. The present invention is not to be limited to the following embodiments. Moreover, cross-sectional views of semiconductor devices and camera modules used in the following embodiments are schematic diagrams, and thereby, relationship between thicknesses and widths of layers, ratio of thickness of each layer, etc., are different from real. Furthermore, thicknesses of layers shown in the embodiments are only examples, and therefore, such thicknesses are not definite.

In accordance with one aspect of the present invention, a semiconductor device comprises a semiconductor substrate, a wiring pattern, a through contact, and a metal film. The semiconductor substrate has a semiconductor element at a first face. The wiring pattern includes a grounding line and located at a side of a second face opposite to the first face of the semiconductor substrate. The through contact penetrates the semiconductor substrate from the first face to the second face, and electrically connects the semiconductor element and the wiring pattern. The metal film is located between the second face of the semiconductor substrate and a face where the wiring pattern exists, and being electrically connected with the grounding line.

In accordance with another aspect of the present invention, a camera module comprises a semiconductor device, a lens unit, and a housing. The semiconductor device has a semiconductor substrate, a wiring pattern, a through contact, and a metal film. The semiconductor substrate has a semiconductor element at a first face. The wiring pattern includes a grounding line and located at a side of a second face opposite to the first face of the semiconductor substrate. The through contact penetrates the semiconductor substrate from the first face to the second face, and is electrically connecting the semiconductor element and the wiring pattern. The metal film is located between the second face of the semiconductor substrate and a face where the wiring pattern exists, and is electrically connected with the grounding line. The lens unit is arranged at a side of the first face of the semiconductor device. The housing holds the semiconductor device and the lens unit.

In accordance with another aspect of the present invention, a method of manufacturing a semiconductor device comprises: forming a contact hole penetrating a semiconductor substrate with a semiconductor element at a first face from the first face to a second face opposite to the first face; forming a metal film at a side of the second face of the semiconductor substrate, the metal film being electrically connected with the semiconductor substrate; forming an insulator covering the metal film while exposing a part of the metal film; and forming a wiring pattern including a grounding line electrically connected with the metal film via the exposed portion on the insulator while forming a through contact penetrating the semiconductor substrate in the contact hole.

### First Embodiment

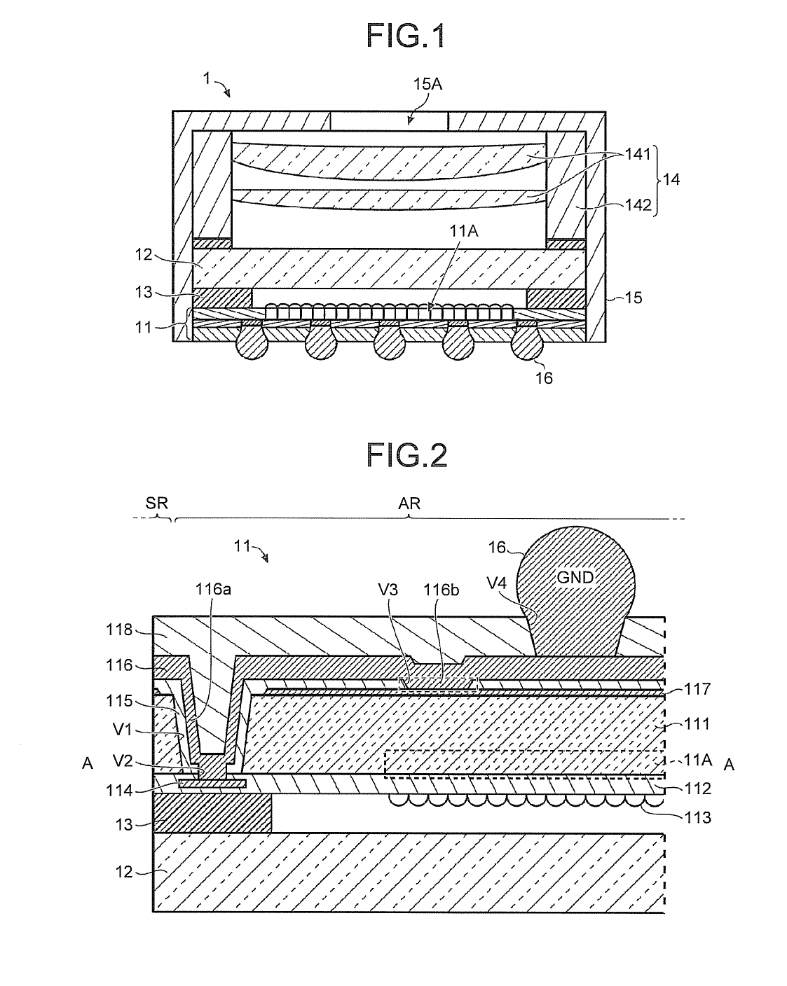

In the following, a semiconductor device, a camera module and a method of manufacturing a semiconductor device according to a first embodiment of the present invention will be described in detail with reference to the accompanying drawings. FIG. 1 is a cross-sectional schematic diagram showing an outline structure of a camera module according to the first embodiment. In FIG. 1, the cross-sectional diagram shows a camera module 1 being cut at a face perpendicular to a face on which a solid-state image sensor 11A is formed in a semiconductor substrate of a semiconductor device 11.

As shown in FIG. 1, the camera module 1 has a semiconductor device 11 with the solid-state image sensor 11A, a cover glass 12 arranged at a side of a receiving face (hereinafter to be referred to as first face) of the solid-state image sensor 11A of the semiconductor device 11, an adhesive layer 13 fixing the cover glass 12 to the semiconductor device 11, a lens unit 14 arranged at the side of the first face of the solid-state image sensor 11A in the semiconductor device 11 via the cover glass 12, and a camera housing 15 housing the semiconductor device 11 to which the cover glass 12 is fixed and the lens unit 14. At a side of a surface (hereinafter to be referred to as second face) opposite to the surface on which the solid-state image sensor 11A in the semiconductor device 11 is formed, solder bumps 16 are mounted as external connection terminals.

In the above description, the solid-state image sensor 11A is a semiconductor element constructed from a CMOS (complementary metal oxide semiconductor) sensor, a CCD (charge coupled device) sensor, or the like, for instance. The lens unit 14 is constructed from one or more lenses 141 transcribing light having entered via an optical window 15A of the camera housing 15 on the receiving face of the solid-state image sensor 11A, and a lens holder 142 holding the lenses 141.

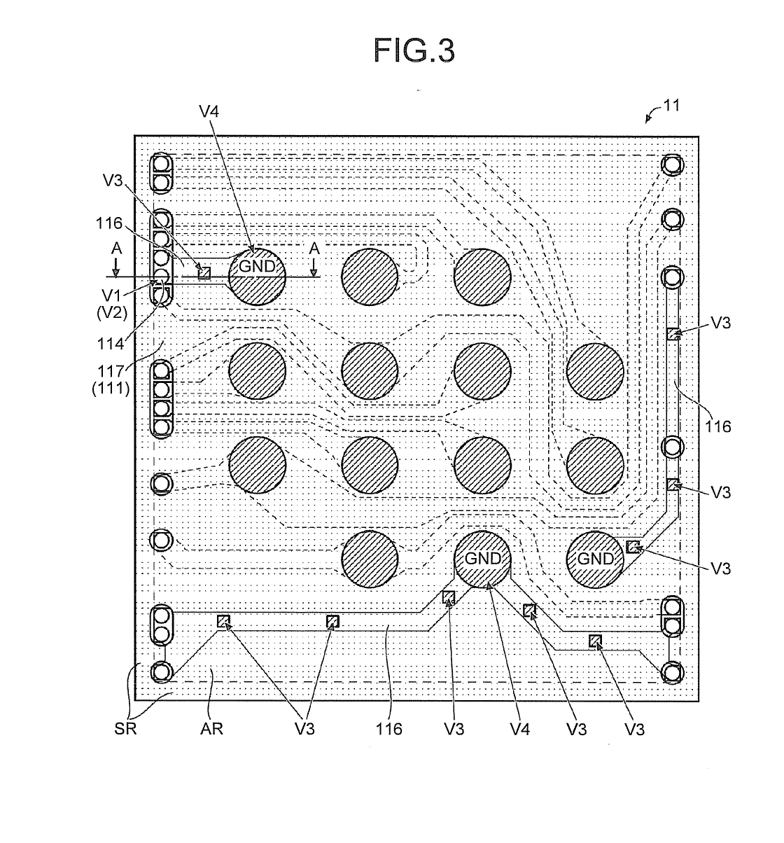

Next, the semiconductor device 11 according to the first embodiment will be described in detail with reference to FIGS. 2 and 3. FIG. 2 is a cross-sectional schematic diagram showing an outline structure of the semiconductor device 11 according to the first embodiment. FIG. 3 is an overhead view showing an outline structure of the semiconductor device 11. For convenience of explanation, FIG. 3 selectively shows a part of layers of the semiconductor device 11. FIG. 2 is an A-A cross-sectional diagram of FIG. 3.

As shown in FIG. 2, the semiconductor device 11 has a semiconductor substrate 111 where the solid-state image sensor 11A is formed on the first face, a filter layer 112 formed on the first face of the semiconductor substrate 111, a micro lens array 113 for focusing being formed at a position corresponding to the solid-state image sensor 11A at the side of the first face of the semiconductor substrate 111 via the filter layer 112, electrode pads 114 formed at the side of the first face of the semiconductor substrate 111 while being electrically connected with the solid-state image sensor 11A, through contacts 116a penetrating the semiconductor substrate 111 from the first face to the second face and drawing an electrical connection with the electrode pads 114 to the second face of the semiconductor substrate 111, wiring patterns 116 formed at the side of the second face of the semiconductor substrate 111, an insulator 115 preventing the semiconductor substrate 111 from directly contacting with the wiring patterns 116 and the through contacts 116a, a GND plane 117 formed between the second face of the semiconductor substrate 111 and a surface (or layer) where the wiring patterns 116 exists, GND contacts 116b penetrating the insulator 115 and electrically connecting the wiring patterns 116 and the GND plane 117, an insulating resin solder resist 118 protecting the second face of the semiconductor substrate 111 on which the wiring patterns 116 are formed, and the solder bumps 16 as being external connection terminals electrically contacted with the wiring patterns 116 via the solder resist 118. Over the semiconductor device 11, the cover glass 12 arranged at the side of the first face of the semiconductor substrate 111 and the adhesive layer 13 fixing the cover glass 12 to the semiconductor substrate 111 are mounted.

As the semiconductor substrate 111, a silicon (111) substrate of which thickness is thinned to be equal to or less than 100 μm, for instance, can be adopted. In a case where a CMOS sensor is adopted to the solid-state image sensor 11A, the solid-state image sensor 11A has a structure in that a single pixel is constructed from one or more semiconductor elements and a plurality of the pixels are arrayed on the first face of the semiconductor substrate 111 in a form of two-dimensional array. In at least a region in the first face of the semiconductor substrate 111 where the solid-state image sensor 11A is formed, a filter layer 112 including color filters corresponding to pixels of RGB and a passivation is formed. The filter layer 112 can include a shielding film covering a region in the first face of the semiconductor substrate 111 where the solid-state image sensor 11A is not being formed.

To a surface opposite to the semiconductor substrate 111 in the filter layer 112, the cover glass 12 is fixed by the adhesive layer 13. The adhesive layer 13 is formed in a region corresponding to the region at which the solid-state image sensor 11A is not being formed.

At the side of the first face of the semiconductor substrate 111, the electrode pads 114 electrically connected with the solid-state image sensor 11A are formed. As the electrode pads 114, cupper (Cu) films can be used, for instance. However, such arrangement is not definite while it is also possible to adopt various conductive films such as titanium (Ti) film or some metal film or alloy film, or a film stack of such films.

The electrode pads 114 are electrically connected with the wiring pattern 116 formed at the side of the second face of the semiconductor substrate 111 via the through contacts 116a penetrating the semiconductor substrate 111. That is, the solid-state image sensor 11A formed at the side of the semiconductor substrate 111 is drawn to the side of the second face of the semiconductor substrate 111 via wirings (not shown) and the electrode pads 114 formed at the side of the first face, and the through contacts 116a. The wiring pattern 116 includes signal lines electrically connected with solder bumps 16 as being the signal input/output terminals, and grounding lines electrically connected with solder bumps 16 as being grounding terminals (GNDs).

The through contacts 116a are formed inside first via holes (it is also referred to as contact holes) V1 penetrating the semiconductor substrate 111 and inside second via holes V2 formed at the filter layer 112, and electrically connected with the electrode pads 114 being exposed by the second via holes V2. On a surface of the inside of the first via holes V1, the insulator 115 is formed, whereby direct connections between the through contacts 116a and the semiconductor substrate 111 are prevented. The insulator 115 also extends over the second face of the semiconductor substrate 111, whereby direct connections between the wiring pattern 116 on the side of the second face and the semiconductor substrate 111 are prevented.

The through contacts 116a and the wiring pattern 116 are formed in the same conductive layer, for instance. As the conductive layer, for instance, it may be possible to adopt a Cu film with a film stack of Ti and Cu as a foundation layer. And a thickness of the film may be about 5 μm, for instance.

At the side of the second face of the semiconductor substrate 111 where the wiring pattern 116 formed, the insulative solder resist 118 is formed in order to make a liquid solder self-aligned on predetermined positions when of the solder bumps 16 are formed, and to protect the semiconductor substrate 111 from being heated. The solder resist 118 can be formed from an epoxy system insulating resin having photosensitivity, for instance. At the solder resist 118, fourth via holes V4 each of which having the solder bump 16 is being selectively mounted are formed.

Over the second face of the semiconductor substrate 111, i.e. between the semiconductor substrate 111 and the insulator 115, the GND plane 117 made from a Ti film with a thickness of about 100 nm, for instance, is formed. However, such arrangement is not definite while it is also possible to adopt various conductive films such as some metal film or alloy film, or a film stack of such films.

As shown in FIG. 3, the GND plane 117 is formed at a region AR in the second face, which corresponds to a region (element formation region) in the first face where semiconductor elements including the solid-state image sensor 11A are formed. In the first embodiment, the GND plane 117 is formed on the entire second face of the semiconductor substrate 111, for instance. In the first embodiment, however the GND plane 117 is not formed at least inside and around the first via holes V1 being formed in the semiconductor substrate 111. In other words, the GND plane 117 opens the first via holes in view from the side of the second face.

The GND plane 117 is electrically connected with the grounding lines in the wiring pattern 116 formed at the side of the second face via the GND contacts 116b. Here, the GND contacts 116b may be portions formed inside the insulator 115 among the wiring pattern 116. The portions formed inside the insulator 115 in the wiring pattern 116 are portions inside third via holes V3 formed at the insulator 115 so as to expose the GND plane 117. However, such arrangement is not definite while it is also possible to additionally form plugs penetrating the insulator 115, for instance. In FIG. 3, only the grounding lines among the wiring pattern 116 formed at the side of the second face are shown by continuous lines, and the other lines such as the signal lines connected with terminals other than the grounding terminals (GNDs) are shown by broken lines.

Thus, by forming the grounded conductive layer over the whole surface (second face) of the semiconductor substrate 111 at the side at which the wiring pattern 116 is formed, it may be possible to prevent parasitic capacitance and parasitic resistance between the semiconductor substrate 111 and the wiring pattern 116 from occurring while it may be possible to surely maintain the semiconductor substrate 111 at a grounding potential even if the substrate itself has a high resistance. As a result, it may be possible to prevent a waveform of high-frequency signal that transmits the wiring pattern 116 from dulling, whereby it may be possible to realize the high-speed operable semiconductor device 11. Moreover, by arranging the conductive layer maintained at the grounding potential between the wiring pattern 116 and the semiconductor substrate 111, it may be possible to prevent electrical noise from the semiconductor elements from being inputted to the wiring pattern 116 using the conductive layer, and therefore, it may be possible to realize the high-performance semiconductor device 11 and the camera module 1.

As the GND plane 117 a film being able to shade at least visible light is adopted, for instance. By using the film with a light blocking effect as the GND plane 117, it may be possible to prevent light entering from the back face (second face) of the semiconductor substrate 111 from entering the solid-state image sensor 11A as formed on the upper face (first face) of the semiconductor substrate 111 via the semiconductor substrate 111. Therefore, it may be possible to avoid appearance of ghosts and capture of the wiring pattern on the back face of the semiconductor substrate on the image, etc. Furthermore, if external stress is applied to the semiconductor substrate 111 constructed from a thinned silicon via the solder bumps 16, for instance, cracks may easily occur at the hard and brittle silicon. On the other hand, in the first embodiment, because a composite substrate lined with the metal to be the GND plane 117 is used as the semiconductor substrate 111, a mechanical strength of the semiconductor substrate 111 increases whereby the highly reliable semiconductor device 11 can be provided.

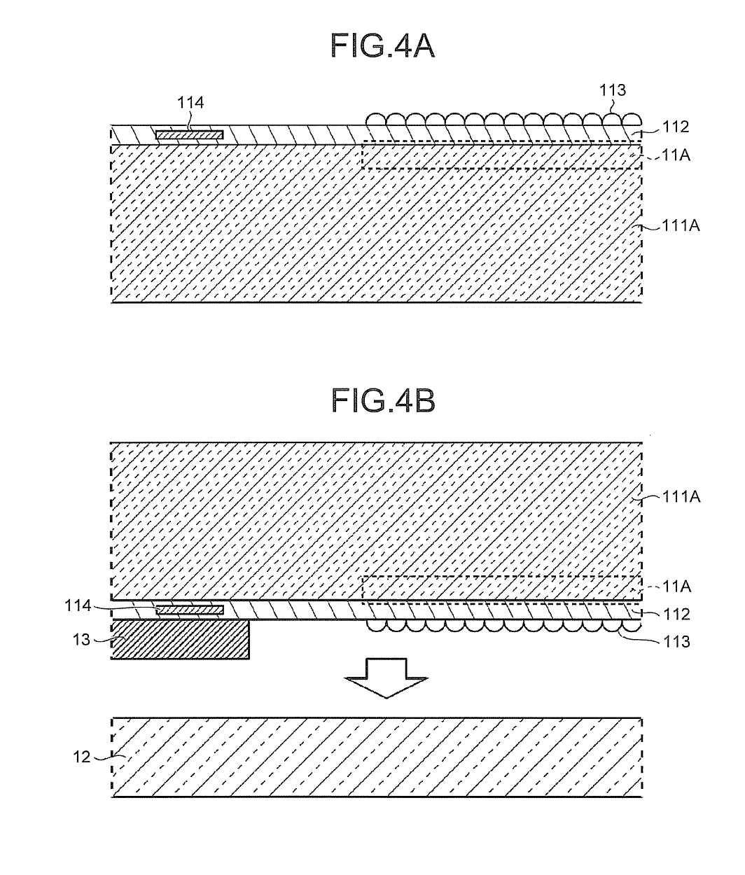

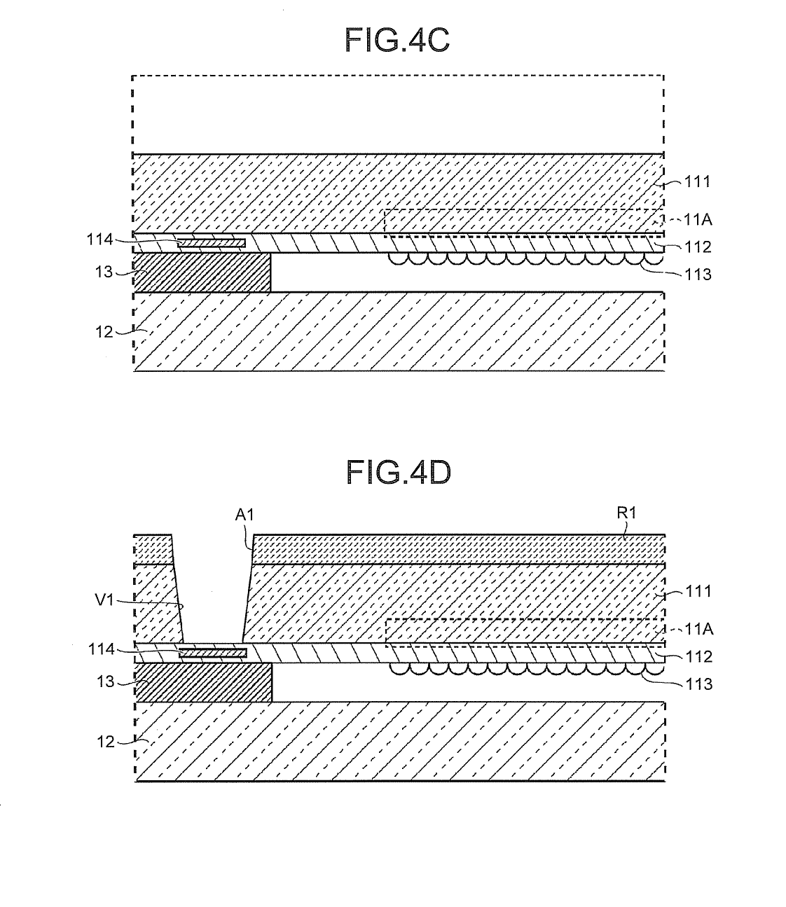

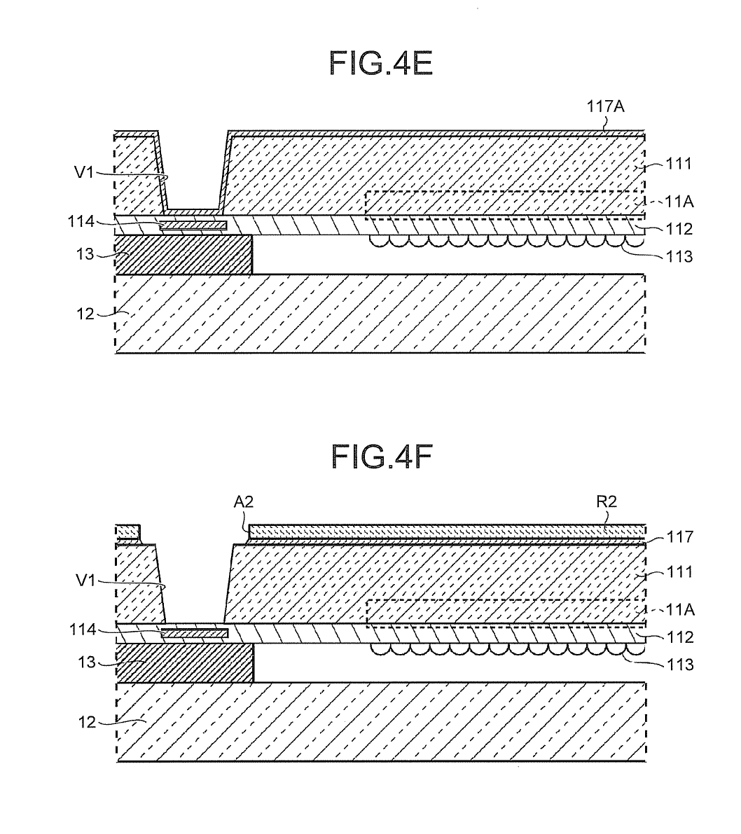

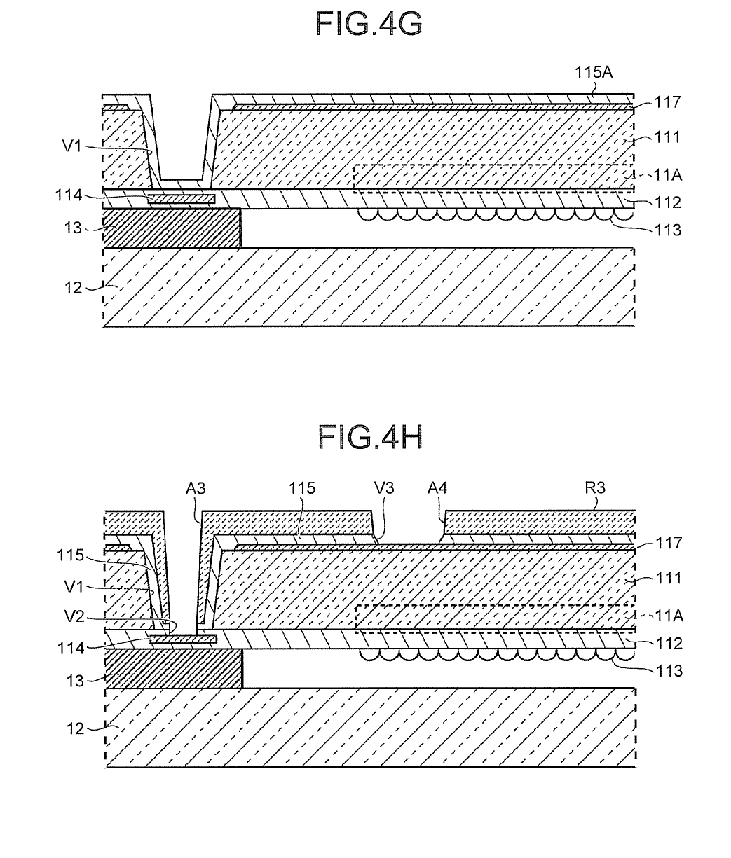

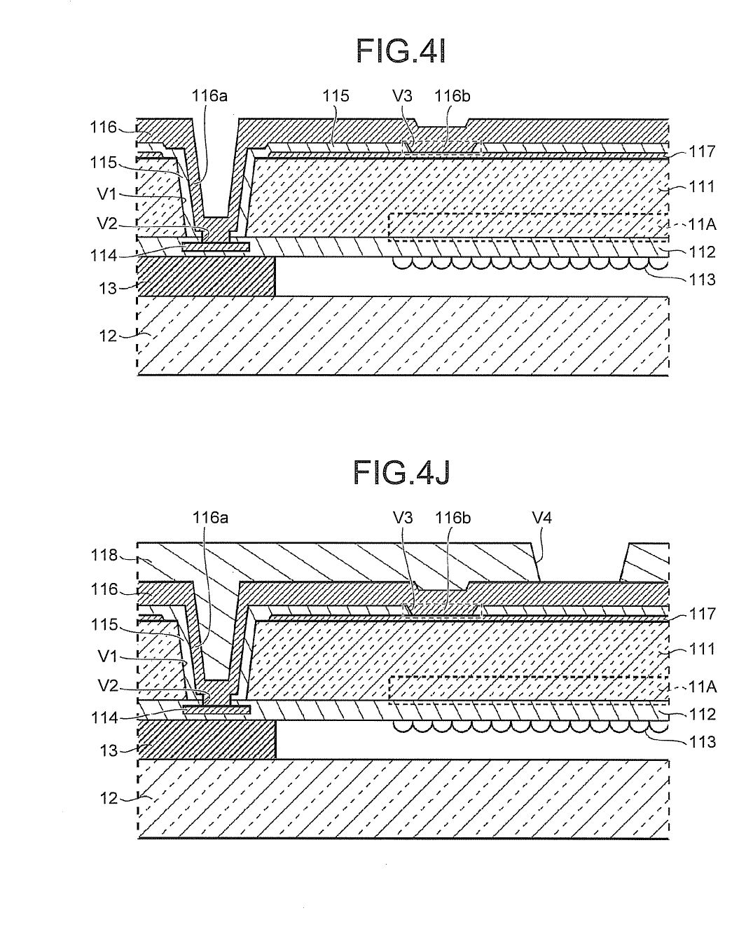

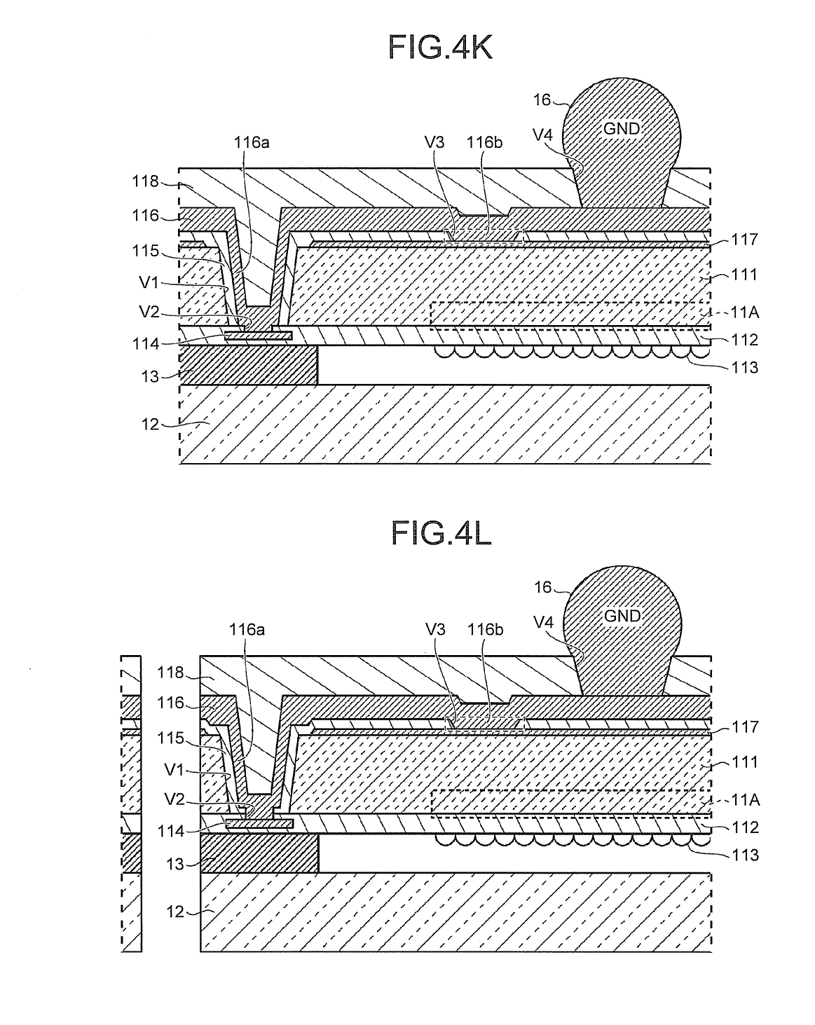

Next, a method of manufacturing the camera module 1 according to the first embodiment will be described in detail with reference to the accompanying drawings. FIGS. 4A to 4L are process illustrations showing a manufacturing method of the camera module according to the first embodiment. In a manufacturing method of the semiconductor device 11 according to the first embodiment, a so-called W-CSP (wafer level chip size package) in which a plurality of semiconductor devices are formed in a single wafer is applied. In the following, for the convenience of explanation, a single chip (semiconductor device 11) will be focused in particular.

In the manufacturing method, firstly, after forming the solid-state image sensor 11A at the side of the first face of the semiconductor substrate 111A such as a silicon wafer, wirings, the filter layer 112 and the micro lens array 113 are formed over the first face in that order. By this formations, a cross-sectional structure as shown in FIG. 4A can be obtained. In FIG. 4A, in the wiring formed over the first face of the semiconductor substrate 111, the electrode pad 114 is selectively shown.

Next, the semiconductor substrate 111A where the filter layer 112 and the micro lens array 113 are being formed is coated with a photo sensitive adhesive, and then, by patterning the adhesive agent, the adhesive layer 13 is formed. The adhesive layer 13 functions as an adhesive portion for fixing the cover glass 12 to the semiconductor substrate 111A (111), and further, functions as a spacer securing a space between the cover glass 12 and the micro lens array 113. By securing a space between the cover glass 12 and the micro lens array 113, it may be possible to prevent focusing efficacy of each micro lens from deteriorating. Then, by affixing the semiconductor substrate 111A to the cover glass 12 in a state of the semiconductor substrate 111A being reversed, a cross-sectional structure shown in FIG. 4B can be obtained.

Next, as shown in FIG. 4C, the semiconductor substrate 111A is thinned from the side of the second face. The thinning of the semiconductor substrate 111A can be executed by combining grinding, CMP (chemical mechanical polishing) and wet etching as necessary, for instance. It is preferable that a thickness of the thinned semiconductor substrate 111 is equal to or less than approximately 50 to 100 μm. Thereby, it may be possible to further downsize and thin the semiconductor device 11 while maintaining rigidity of the semiconductor device 11, and it may be possible to effectively drain electrical charge accumulated in the semiconductor substrate 111 via the GND plane 117 to be described later on. As a result, it may be possible to improve the characteristic of the semiconductor device 11.

Next, a resist R1 is formed on the second face of the thinned semiconductor substrate 111 by photolithography. The resist R1 has a pattern in that an aperture A1 is formed at a position corresponding to the electrode pad 114, i.e. a region where the first via hole V1 is to be formed. Then, by etching the semiconductor substrate 111 from the side of the second face by a RIE (reactive ion etching) using the resist R1 as a mask, as shown in FIG. 4, the first via hole V1 penetrating the semiconductor substrate 111 from the first face to the second face is formed.

Next, after exfoliating the resist R1, a metal film 117A covering the second face of the semiconductor substrate 111 is formed, as shown in FIG. 4E, by depositing Ti on the second face of the semiconductor substrate 111 where the first via hole V1 is being formed by using a sputtering method, for instance. In this process, a thickness of the metal film 117A can be about 100 μm, for instance. In addition, as the deposited metal, beside Ti, tantalum (Ta), Cu, nickel (Ni) or iron (Fe) can be applied. However, considering influence of a metal to the semiconductor substrate 111, it is preferred that a metal such as Ti and Ta, of which influence to the semiconductor substrate 111 is minor is adopted. Moreover, when a silicidable metal is used as the deposited metal, by progressing siliciding reaction at an interface between the semiconductor substrate 111 and the metal film 117A, good electrical connections between them can be obtained, whereby it may be possible to effectively drain electrical charge from the semiconductor substrate 111 via the GND plane 117.

Next, a resist R2 is formed at the side of the second face of the semiconductor substrate 111 covered with the metal film 117A by photolithography. The resist R2 has a pattern at which an aperture A2 is formed at and around the first via hole V1. As a mark to be used for positioning at a time of formation of the resist R2 a concave pattern of the metal film 117A formed at the first via hole V1 can be adopted, for instance. Then, by etching the metal film 117A by wet etching of RIE using the resist R2 as a mask, the metal film 117A at and around the first via hole V1 is removed as shown in FIG. 4F.

It is sufficient as long as the removed portion around the first via hole V1 is the metal film 117A in an area to the extent that at least an exposure margin at a time of formation of the resist R2 can be absorbed. Moreover, when the metal film 117A around the first via hole V1 is removed while having a sufficient margin with respect to the exposure margin, it may be possible to form the GND plane 117 before formation of the first via hole V1. That is, the process of forming the first via hole shown in FIG. 4D and the process of forming the GND plane shown in FIGS. 4E to 4F can be permutated. In this case, because the second face of the semiconductor substrate 111 is plane, although there may be a case where offset at a time of opening the resist for patterning the metal film becomes large, by removing the metal film 117A around the first via hole V1 with a sufficient margin as described above, it may be possible to prevent the metal film 117A to be processed into the GND plane 117 from remaining inside the first via hole V1 (especially, a portion where the second via hole V2 is to be formed), and as a result, it may be possible to avoid the solid-state image sensor 11A from being unnecessarily grounded via the electrode pad 114. In a process after the formation of the GND plane 117, an aperture of the GND plane 117 around the first via hole V1 can be used for alignment.

As described above, after forming the GND plane 117 on the second face of the semiconductor substrate 111 and exfoliating the resist R2, as shown in FIG. 4G, an insulator 115A is formed on the second face of the semiconductor substrate 111 where the GND plane 117 is being formed. The insulator 115A can be an inorganic insulator such as a silicon oxide film (SiO₂), a silicon nitride film (SiN), or the like, and also be an organic insulator such as an insulating resin. When the insulator 115A is an inorganic insulator, it may be possible to form the insulator 115A by a CVD (chemical vapor deposition), and so forth, for instance. On the other hand, when the insulator 115A is an organic insulator, it may be possible to form the insulator 115A by an ink-jet printing technique, and so forth.

Next, a resist R3 is formed by photolithography at the side of the second face of the semiconductor substrate 111 where the insulator 115A is being formed. The resist R3 has a pattern in that an aperture A3 is formed at a bottom of the first via hole V1. The pattern includes an aperture A4 formed at a position corresponding toe the grounding line in the wiring pattern 116 which is to be formed in the following process. Then, by etching the insulator 115A (it may be possible to include the filter layer 12 as necessary) by RIE using the resist R3 as a mask, as shown in FIG. 4H, the second via hole V2, which exposes the electrode pad 114 formed at the side of the first face of the semiconductor substrate 111, is formed at the bottom of the first via hole V1 while the third via hole V3 exposing the GND plane 117 is formed at a position corresponding to the grounding line in the wiring pattern 116. Thus, by forming the second via hole V2 for establishing an electrical connection with the electrode pad 114 and the third via hole V3 for establishing an electrical connection with the GND plane 117 in the single process, it may be possible to simplify the processes.

Next, after exfoliating the resist R3, as shown in FIG. 4I, the wiring pattern 116 is formed on the second face of the semiconductor substrate 111 where the second via hole V2 and the third via hole V3 are being formed. The wiring pattern 116 includes the through contact 116a formed inside the first via hole V1 and the second via hole V2, and the GND contact 116b formed inside the third via hole V3. For the formation of the wiring pattern 116 including the through contact 116a and the GND contact 116b, it may be possible to adopt an electrolytic plating method, for instance. As a specific example, firstly, a Ti film functioning as a barrier metal and a Cu film functioning as a seed layer at the time of plating are formed at the whole side of the second face of the semiconductor substrate 111 by a sputtering method, for instance, and then by executing a photolithography process, a resist with an aperture of which opening shape is the same as the wiring pattern 116 is formed. Then, a Cu film is formed by an electrolytic plating where the Cu film is used as the seed layer while the resist is used as a mask. After that, after exfoliating the resist used as the mask, the Cu film being the seed layer and the Ti film being the barrier metal are patterned by etching while using the Cu film formed by the electrolytic plating as a mask. Accordingly, the wiring pattern 116 made from Cu is formed.

Next, solution of solder resist is applied on the side of the second face of the semiconductor substrate where the wiring pattern 116 is being formed. Then, after drying the solution, by patterning the solution by a photolithography process and an etching process, the solder resist 18 with the fourth via hole V4 being formed at a position where the solder bump 16 is mounted is formed, as shown in FIG. 4J.

Next, by using the known ball mounting apparatus, the solder bump 16 is mounted at the fourth via hole V4 at the predetermined position in the side of the second face of the semiconductor substrate 111 where the solder resist 118 is being formed, as shown in FIG. 4K. Then, by dicing the semiconductor substrate 111 along a scribe region SR (cf. FIG. 3) using a diamond cutter or a laser light, the semiconductor wafer with the two-dimensional arrayed semiconductor devices 11 is cut in pieces with each of the semiconductor devices 11, as shown in FIG. 4L. After that, by mounting the chipped semiconductor device 11 on the camera housing 15 together with the lens unit 14, the camera module 1 having the cross-sectional structure shown in FIG. 1 is manufactured.

As described above, the semiconductor device 11 according to the first embodiment comprises the semiconductor substrate 111 having the solid-state image sensor 11A as being a semiconductor element on the first face, the wiring pattern 116 formed at the side of the second face of the semiconductor substrate 111, the wiring pattern 116 including the grounding lines in at least a part thereof, the through contact 116a penetrating the semiconductor substrate 111 from the first face to the second face, the through contact 116a electrically connecting the solid-state image sensor 11A and the wiring pattern 116, the GND pattern 117 formed between the second face of the semiconductor substrate 111 and the face (or the layer) where the wiring pattern 116 expands, the GND plane 117 electrically connected with the semiconductor substrate 111 and the grounding line of the wiring pattern 116. That is, in the first embodiment, the GND plane 117 with grounding potential, which functions as a shading film, is arranged between the semiconductor substrate 111 and the wiring pattern 116. Therefore, it may be possible to prevent light from the back side face (second face) of the semiconductor substrate 111 from entering the solid-state image sensor 11A formed at the upper face (first face) of the semiconductor substrate 111 via the semiconductor substrate 111 while inhibiting capacitive coupling of the semiconductor substrate 111 and the wiring pattern 116. As a result, it may be possible to realize the semiconductor device 11 and the camera module 1 with high-speed operation while avoiding appearance of ghosts, capture of the wiring pattern, etc.

### Alternate Example 1-1

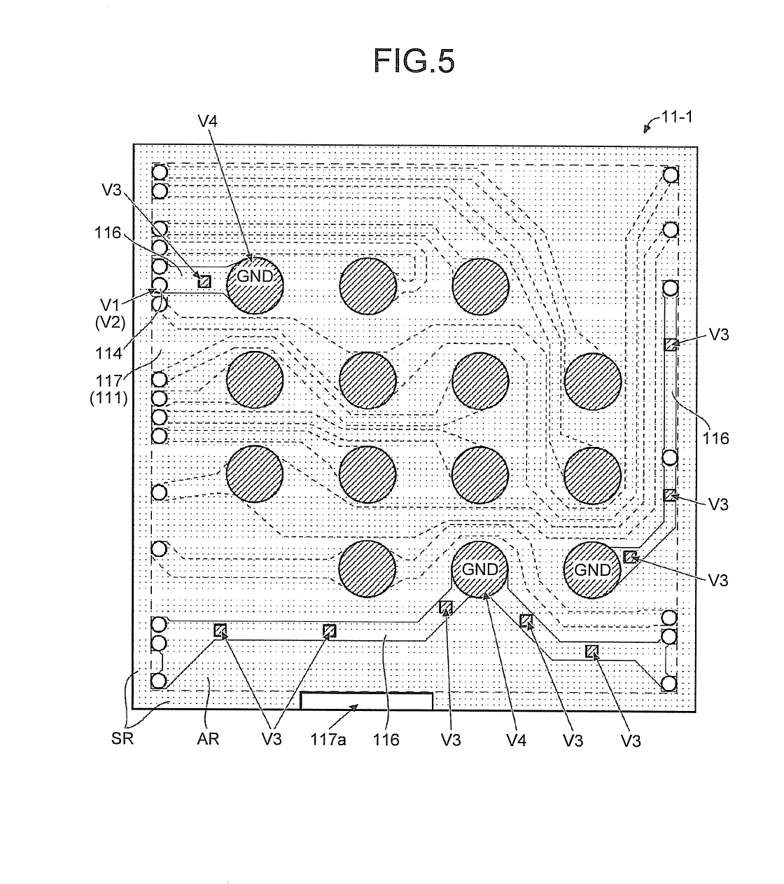

In the first embodiment descried above, the shape of the first via hole V1 is used as the alignment mark in the exposure for patterning the GND plane 117 by photolithography. However, as shown in FIG. 5, for instance, it may be possible to form an aperture 117a as an alignment mark at the GND plane 117 (the metal film 117A). In the following, this case will be described in detail as an alternate example 1-1 of the first embodiment with reference to the accompanying drawings.

FIG. 5 is an overhead view showing an outline structure of a semiconductor device according to the alternate example 1-1. For convenience of explanation, in FIG. 5, a part of layers of the semiconductor device 11-1 is shown selectively. As shown in FIG. 5, the semiconductor device 11-1 according to the alternate example 1-1 has the aperture 117a that exposes the insulator 115 lying under the GND plane 117 at a predetermined region of the GND plane 117 corresponding to a position where an alignment mark (not shown) is arranged in the semiconductor substrate 111.

As described above, the solid-state image sensor 11A being a semiconductor element is formed in an element region internally by a predetermined length from an outer edge of the first face of the chipped semiconductor substrate 111. In the alternate example 1-1, the aperture 117a is formed at a predetermined region AR in the GND plane 117 corresponding to the element region in view from the side of the second face of the semiconductor substrate 111. For instance, the aperture 117a is formed on a dicing line which is a cutting area at a time of cutting the semiconductor device 11-1 into a piece. Thereby, it may be possible to use the alignment mark formed at the semiconductor substrate 111 for exposure while avoiding the capacitance coupling between the wiring pattern 116 and the semiconductor substrate 111 from increasing.

The aperture 117a is formed by a liftoff process in a process of forming the metal film 117A, for instance. That is, in the alternate example 1-1, before forming the metal film 117A at the second face of the semiconductor substrate 111, a resist is formed by photolithography on the scribe region SR which is to be cut off at the time of cutting the semiconductor device into a piece. Then, by forming the metal film 117A by depositing metal such as Ti, or the like, using a sputtering method, for instance, on the second face of the semiconductor substrate 111 where the resist is being formed, and then removing the resist using exfoliative solution such as acetone, a part of the metal film 117A on the resist is removed (lifted off) together with the resist. Thereby, the aperture 117a is formed over the scribe region SR.

Moreover, as in the alternate example 1-1, by forming the aperture 117a at the metal film 117A before patterning the metal film 117A into the GND plane 117, it may be possible to accurately execute the alignment at the time of exposure based on the aperture 117a, whereby it may be possible to reduce an exposure margin around the first via hole V1 in the process of patterning the metal film 117A into the GND plane 117. Since the rest of the structures, manufacturing processes and effects are the same as in the above-described embodiment, detailed descriptions thereof will be omitted.

### Alternate Example 1-2

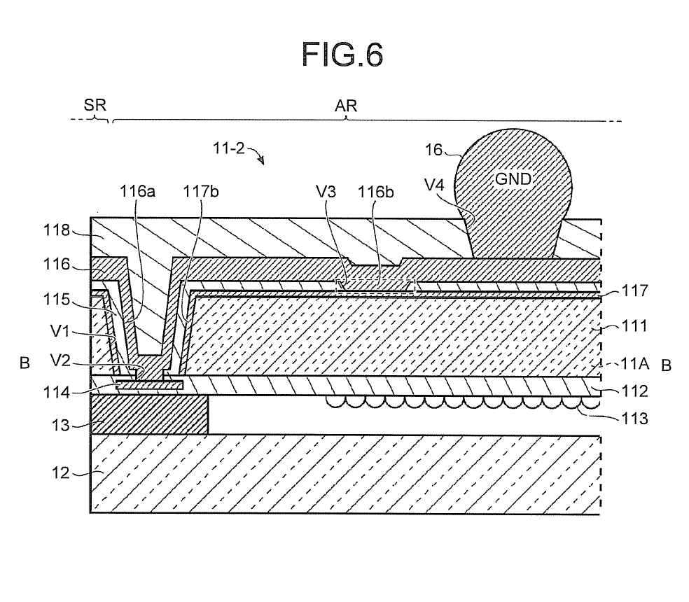

In the first embodiment, the metal film 117A inside the first via hole V1 is removed. That is, in the first embodiment, the GND plane 117 does not exist inside the first via hole V1. However, as shown in FIG. 6, for instance, the GND plane 117 can be extended to a side surface in the first via hole V1. In other words, the GND plane 117 can include an internal via GND plane 117b formed at the side surface in the first via hole V1. In the following, this case will be described in detail as an alternate example 1-2 of the first embodiment with reference to the accompanying drawings.

FIG. 6 is a cross-sectional view showing an outline structure of a semiconductor device 11-2 according to the alternate example 1-2. For convenience of explanation, in FIG. 6, a cross-section of the semiconductor device 11-2 at a portion (line B-B) corresponding to the line A-A in FIG. 3 will be shown. As shown in FIG. 6, the semiconductor device 11-2 according to the alternate example 1-2 has the GND plane 117 and the internal via GND plane 117b extending to the side surface in the first via hole V1 from the second face of the semiconductor substrate 111. By this structure, it may be possible to prevent the through contact 116a in the first via hole V1 and the semiconductor substrate 111 from capacitatively coupling, and as a result, it may be possible to improve a characteristic of the semiconductor device 11-2.

Here, as in the alternate example 1-1 described above, in this alternate example 1-2 also it is preferred that the aperture 117a is formed at the GND plane 117 of the scribe region SR. Since the rest of the structures, manufacturing processes and effects are the same as in the above-described embodiment or alternate examples, detailed descriptions thereof will be omitted.

### Alternate Example 1-3

In the above-described embodiment and the alternate examples, a photolithography process and an etching process are used for the patterning of the metal film 117A into the GND plane 117. However, such processes are not definite while the GND plane 117 can be formed using a liftoff method, for instance. In the following, this case will be described in detail as an alternate example 1-3 of the first embodiment with reference to the accompanying drawings. By reference to the explanations of the same processes as in the first embodiment described above, giving redundant explanations of those processes will be omitted.

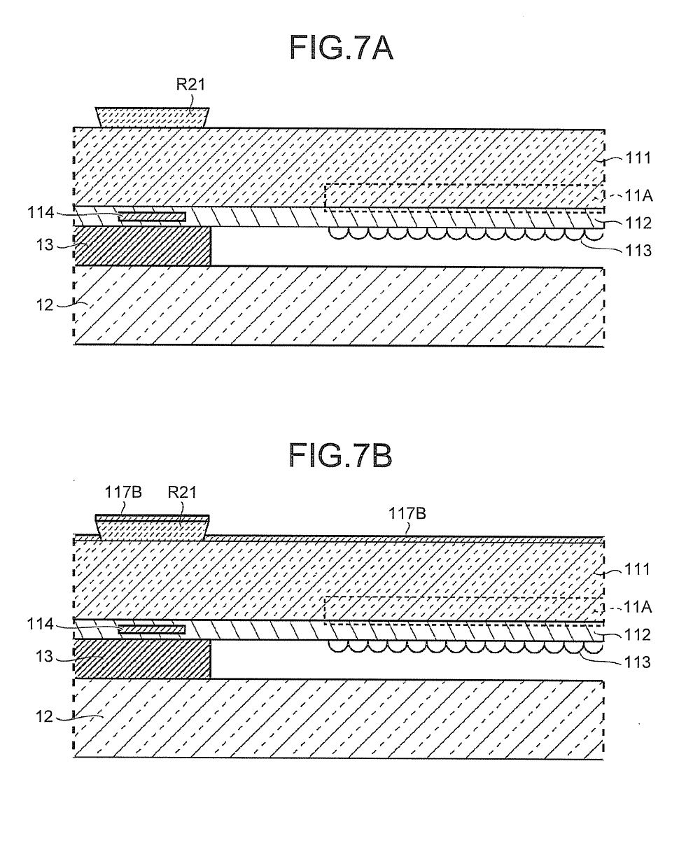

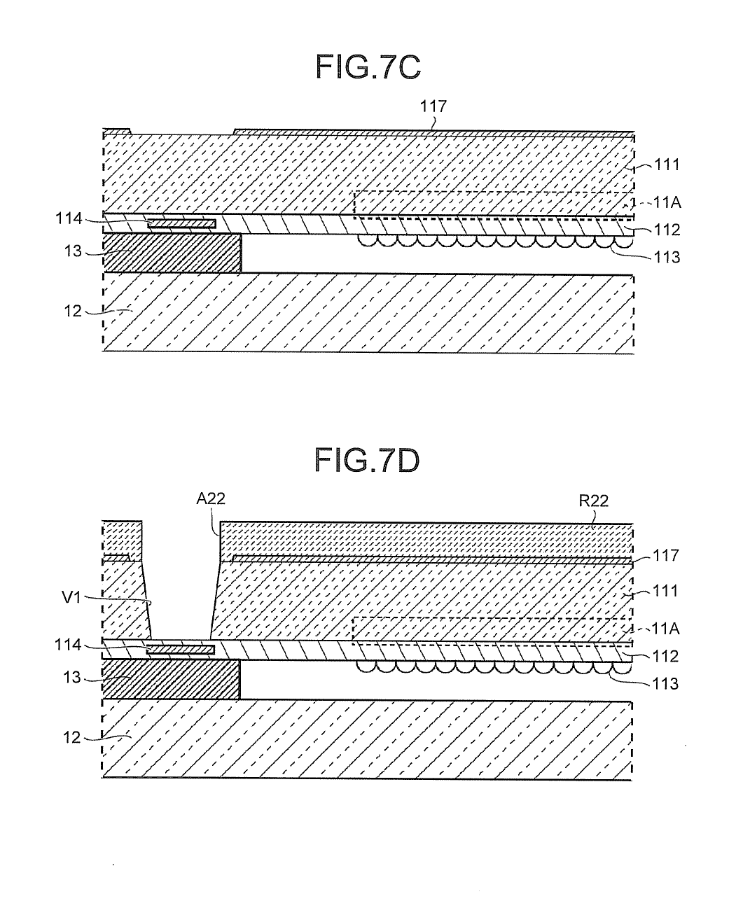

FIGS. 7A to 7D are process illustrations showing a manufacturing method of the camera module according to the alternate example 1-3. In the manufacturing method, firstly, by executing the same processes as the processes described with reference to FIGS. 4A to 4C in the above description, the semiconductor substrate 111A with the solid-state image sensor 11A, the filter layer 112, the micro lens array 113 and the electrode pad 114 being formed is thinned from the side of the second face. To the semiconductor substrate 111, the cover glass 12 is affixed using the adhesive layer 13.

Next, as shown in FIG. 7A, a resist R21 is formed at the second face of the thinned semiconductor substrate 111 by photolithography. The resist R21 has a pattern shape which is negative when a pattern shape of the GND plane 117 is defined as positive. That is, the resist R21 is formed at a region where at least the first via hole V1 is to be formed. However, in the alternate example 1-3, it is preferred that a cross-sectional shape of the resist R21 is a so-called reversed taper shape based on the second face of the semiconductor substrate 111. The reversed taper shape can be realized by adjusting a focal depth and an exposure amount at the exposure, for instance.

Next, by depositing Ti using a sputtering method, for instance, on the second face of the semiconductor substrate 111 with the resist R21 being formed, a metal film 117B is formed on the second face of the semiconductor substrate 111 and the resist R21, as shown in FIG. 7B. Then, the resist R21 is removed using exfoliative solution such as acetone, for instance. Thereby, the metal film 117B on the resist R21 is removed (lifted off) together with the resist R21, and as a result, the patterned GND plane 117 remains on the second face of the semiconductor substrate 111, as shown in FIG. 7C. In this process, by making the cross-sectional shape of the resist R21 be the reversed taper shape, it may be possible to make an edge of the GND plane 117 have a taper shape. Thereby, it may be possible to prevent an electrical field from concentrating at the edge of the GND plane 117 in an operation of the semiconductor device 11.

Next, a resist R22 is formed at the second face of the semiconductor substrate 111 with the GND plane 117 being formed. The resist R22, as the resist R21 explained with reference to FIG. 4D in the above-described first embodiment, has a pattern in that an aperture A22 is formed at a position corresponding to the electrode pad 114, i.e. a region where the first via hole V1 is to be formed. Then, by etching the semiconductor substrate 111 from the side of the second face by a RIE using the resist R22 as a mask, the first via hole V1 penetrating the substrate 111 from the first face to the second face is formed, as shown in FIG. 7D.

Next, by executing the same processes as the processes described with reference to FIGS. 4E to 4H in the above description, the semiconductor substrate 111 having the insulator 115 including the third via hole V3, the wiring pattern 116 including the through contact 116a and the GND contact 116b, and the solder resist 118 and the solder bumps 16 being formed is cut in pieces. After that, as in the first embodiment described above, by mounting the chipped semiconductor device 11 on the camera housing 15 together with the lens unit 14, the camera module 1 having the cross-sectional structure shown in FIG. 1 is manufactured.

As described above, in the alternate example 1-3, before covering the second face of the semiconductor substrate 111 with the metal film 117B, the resist R21 for patterning the GND plane 117 is formed, and therefore, it may be possible to execute an alignment at the exposure with ease and accuracy. As a result, because it may be possible to form the GND plane 117 so as to cover a wider area in the second face of the semiconductor substrate 111, it may be possible to improve a characteristic of the semiconductor device 11. Since the rest of the structures, manufacturing processes and effects are the same as in the above-described embodiment and the alternate examples, detailed descriptions thereof will be omitted.

### Second Embodiment

Next, a semiconductor device, a camera module and a method of manufacturing a semiconductor device according to a second embodiment will be described in detail with reference to the accompanying drawings. In the following, by reference to the explanations of the same structure as in the embodiment or the alternate examples described above, redundant explanations of those structure elements will be omitted.

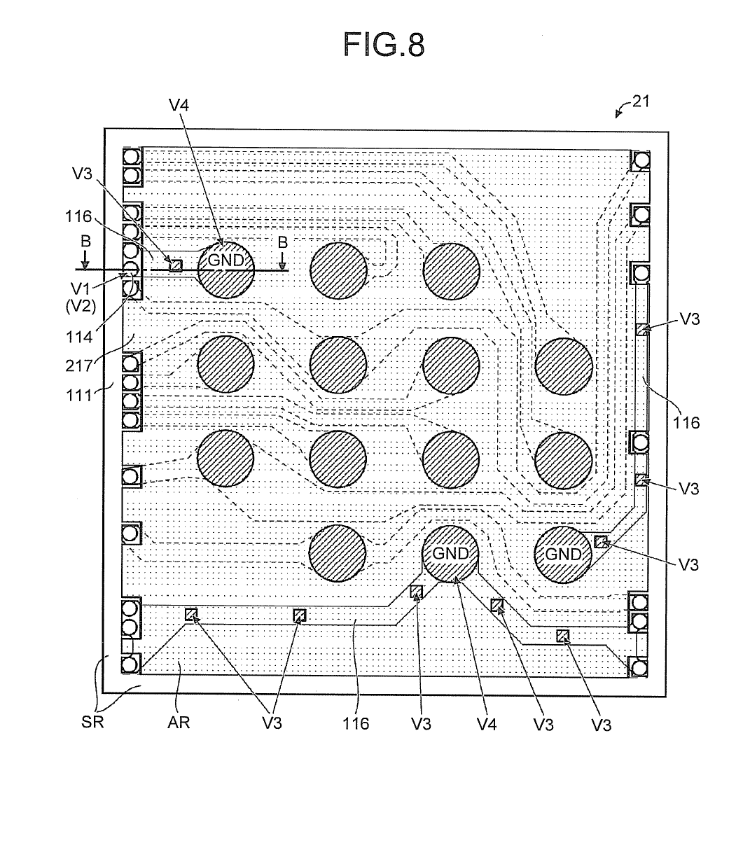

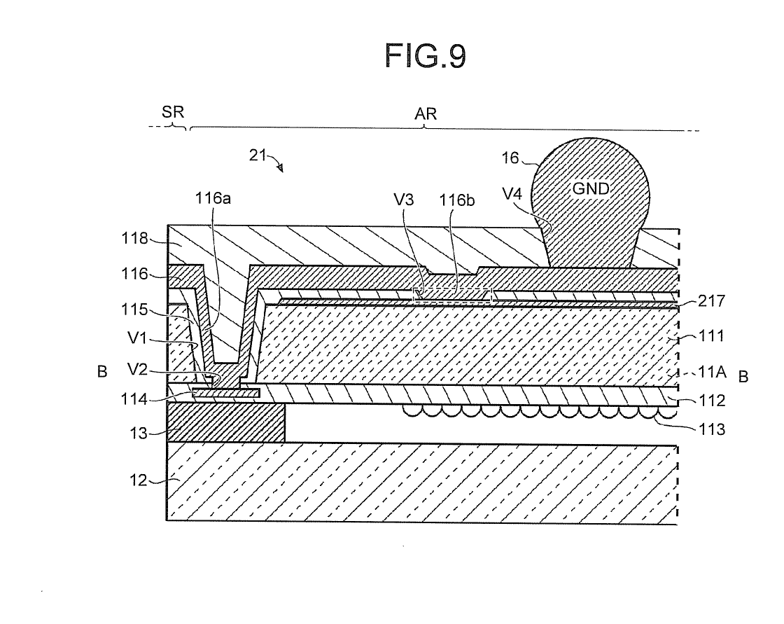

FIG. 8 is an overhead view showing an outline structure of a semiconductor device according to the second embodiment. FIG. 9 is a B-B cross-sectional view showing an outline structure of the semiconductor device shown in FIG. 8. For convenience of explanation, in FIG. 9, a part of layers of the semiconductor device 21 is shown selectively.

As shown in FIGS. 8 and 9, a GND plane 217 in the semiconductor device 21 is not formed at a scribe region SR of which width from an intersection line formed by a dicing face to be diced at a time of cutting to make pieces and the second face is a predetermined length. In other words, the GND plane 217 is formed so as to cover inside a region AR of which edges are respectively separated from sides of the second face of the chipped semiconductor substrate 111.

By having such structure, in the second embodiment, it may be possible to avoid the GND plane 217 from peeling off at a time of dicing. As a result, it may be possible to prevent occurrence of leak current and degradation of device characteristic that can be caused by the GND plane peeling off. Since the rest of the structures, manufacturing processes and effects are the same as in the above-described embodiment and the alternate examples, detailed descriptions thereof will be omitted.

### Third Embodiment

Next, a semiconductor device, a camera module and a method of manufacturing a semiconductor device according to a third embodiment will be described in detail with reference to the accompanying drawings. In the following, by reference to the explanations of the same structure as in the embodiments or the alternate examples described above, redundant explanations of those structure elements will be omitted.

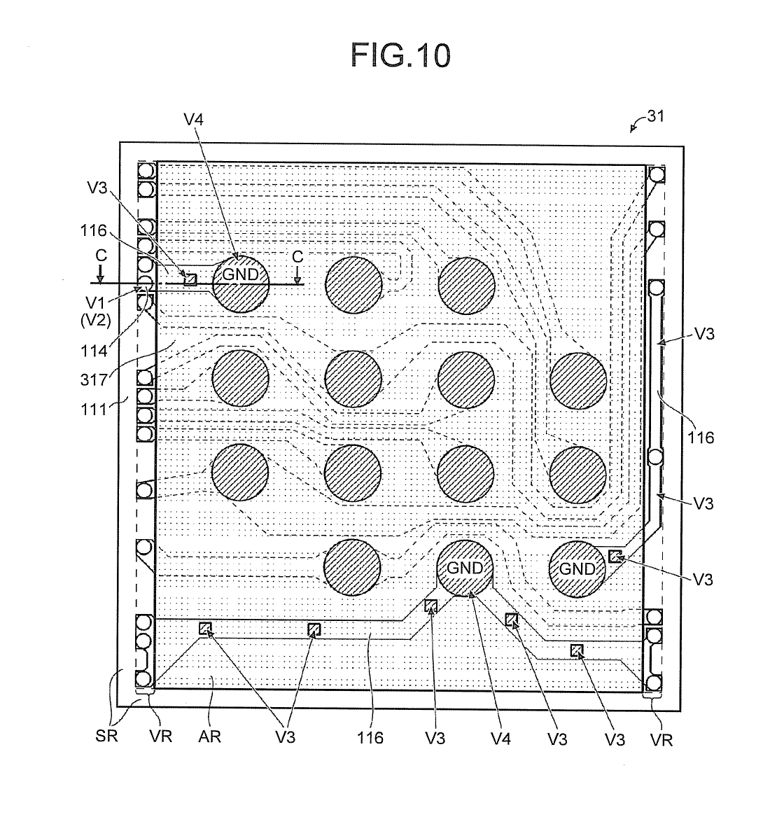

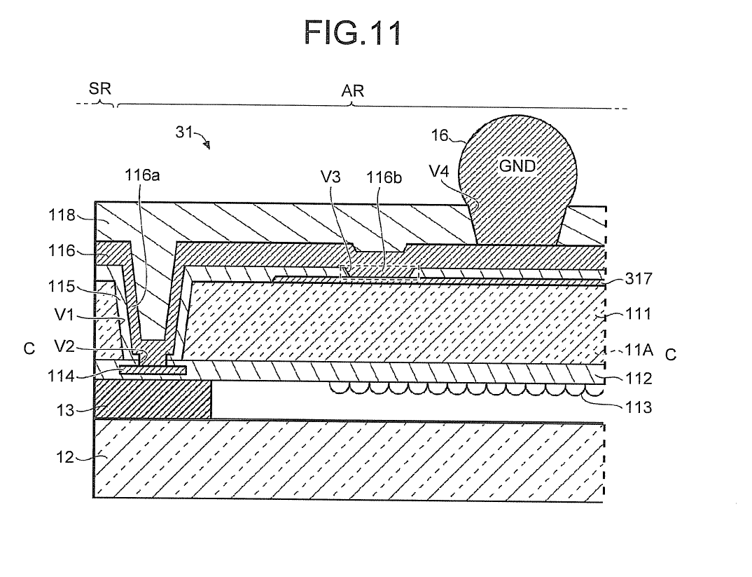

FIG. 10 is an overhead view showing an outline structure of a semiconductor device according to the third embodiment. FIG. 11 is a C-C cross-sectional view showing an outline structure of the semiconductor device shown in FIG. 10. For convenience of explanation, in FIG. 11, a part of layers of the semiconductor device 31 is shown selectively.

As shown in FIGS. 10 and 11, a GND plane 317 in the semiconductor device 31 is formed so as to cover inside a region AR of which edges are respectively separated from intersection lines formed by dicing faces to be diced at a time of cutting to make pieces and the second face of the semiconductor substrate 111. The region AR is formed in a way covering a region that is inside a region of which edges are formed by connecting edges near a center of the second face in the first via holes V1 arraying linearly. Or the GND plane 317 is not formed at a strip-shaped via array region VR surrounding the scribe region SR to be diced at a time of cutting to make pieces and a plurality of the arrayed first via holes V1.

Thus, in the third embodiment, the through contacts 116a are closely arrayed at one or more edges among the edges around the second face of the semiconductor substrate 111, and the GND plane 317 is formed at the region of which edges of the center sides in the second face of the through contacts 116a linearly arraying in view from the side of the second face are inlying. Thereby, in the third embodiment, because it may be possible to avoid the GND plane 317 from peeling off at a time of dicing while the shape for patterning of the GND plane 317 can be simplified, it may be possible to a design the semiconductor device 31 with more ease and simplify manufacture of the semiconductor device 31. Since the rest of the structures, manufacturing processes and effects are the same as in the above-described embodiments and the alternate examples, detailed descriptions thereof will be omitted.

As described above, according to the embodiments, it may be possible to realize the semiconductor devices and the camera modules with high-speed operation while avoiding occurrence of ghost, capture of the wiring pattern, etc., and it may be possible to realize the method of manufacturing the semiconductor device capable of high-speed operation.

While certain embodiments of the invention have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate having a semiconductor element at a first face;
a wiring pattern including a grounding line and located at a side of a second face opposite to the first face of the semiconductor substrate;
a through contact penetrating the semiconductor substrate from the first face to the second face and electrically connecting the semiconductor element and the wiring pattern; and
a metal film located between the second face of the semiconductor substrate and a face where the wiring pattern exists, and electrically connected with the grounding line.

2. The semiconductor device according to claim 1, wherein
the through contact is located inside a contact hole penetrating the semiconductor substrate, and
the metal film opens the contact hole in view from the second face.

3. The semiconductor device according to claim 2, wherein
the aperture opening the metal film is continued from an edge of the metal film.

4. The semiconductor device according to claim 1, wherein
the through contact is located inside a contact hole penetrating the semiconductor substrate, and
the metal film covers the second face and an internal face of the contact hole in view of a side of the second face.

5. The semiconductor device according to claim 1, wherein
the through contact is located inside a contact hole penetrating the semiconductor substrate,
a plurality of the contact holes are arrayed near an exterior edge in view of a side of the second face, and
an edge of the metal film is located inside the array of the contact holes in view of the side of the second face.

6. A camera module comprising:
a semiconductor device having
a semiconductor substrate having a semiconductor element at a first face,
a wiring pattern including a grounding line and located at a side of a second face opposite to the first face of the semiconductor substrate,
a through contact penetrating the semiconductor substrate from the first face to the second face and electrically connecting the semiconductor element and the wiring pattern, and
a metal film located between the second face of the semiconductor substrate and a face where the wiring pattern exists and electrically connected with the grounding line;
a lens unit arranged at a side of the first face of the semiconductor device; and
a housing holding the semiconductor device and the lens unit.

7. The camera module according to claim 6, wherein
the through contact is located inside a contact hole penetrating the semiconductor substrate, and
the metal film opens the contact hole in view from the second face.

8. The camera module according to claim 7, wherein
the aperture opening the metal film is continued from an edge of the metal film.

9. The camera module according to claim 6, wherein
the through contact is located inside a contact hole penetrating the semiconductor substrate, and
the metal film covers the second face and an internal face of the contact hole in view of a side of the second face.

10. The camera module according to claim 6, wherein
the through contact is located inside a contact hole penetrating the semiconductor substrate,
a plurality of the contact holes are arrayed near an exterior edge in view of a side of the second face, and
an edge of the metal film is located inside the array of the contact holes in view of the side of the second face.

11. A method of manufacturing a semiconductor device comprising:
forming a contact hole penetrating a semiconductor substrate with a semiconductor element at a first face from the first face to a second face opposite to the first face;
forming a metal film at a side of the second face of the semiconductor substrate, the metal film being electrically connected with the semiconductor substrate;
forming an insulator covering the metal film while exposing a part of the metal film; and
forming a wiring pattern including a grounding line electrically connected with the metal film via the exposed portion on the insulator while forming a through contact penetrating the semiconductor substrate in the contact hole.

12. The method of manufacturing a semiconductor device according to claim 11, wherein
the metal film is formed so as to open the contact hole in view of the side of the second face.

13. The method of manufacturing a semiconductor device according to claim 12, wherein
the aperture opening the contact hole is continued from an edge of the metal film.

14. The method of manufacturing a semiconductor device according to claim 11, wherein
the metal film is formed so as to cover the second face and an internal face of the contact hole in view of the side of the second face.

15. The method of manufacturing a semiconductor device according to claim 11, wherein
a plurality of the contact holes are arrayed near an exterior edge in view of a side of the second face, and
an edge of the metal film is located inside the array of the contact holes in view of the side of the second face.
